(19) United States
(12) Patent Application Publication
(10) Pub. No.: US 2004/0146170 A1
(43) Pub. Date: Jul. 29, 2004

(54) Graphic audio equalizer with parametric equalizer function

(76) Inventor: Thomas Zint, Willich (DE)

Correspondence Address: COLLARD & ROE, P.C., 1077 Northern Boulevard, Roslyn, NY, 11576-1696, US

(21) Appl. No.: 10/405,292

(22) Filed: Apr. 2, 2003

(30) Foreign Application Priority Data
Jan. 28, 2003 (DE) 103 03 258.4

(51) Int. Cl. H03G 5/00

(52) U.S. Cl. 381/103

(57) ABSTRACT

A graphic audio equalizer alters an audio frequency response in selected frequency bands using a plurality of filters of variable level, fixed frequency band and fixed center-frequency frequency. A circuit simulates the operation of a parametric audio equalizer to alter an audio frequency response in the shape of at least one bell curve defined by center frequency, Q-factor and maximum level, the following functions being implemented in the circuit: selection of one of the fixed frequency bands as the center frequency, selection of further fixed frequency bands on both sides of the fixed frequency band which determines the center frequency in order to stipulate the Q-factor, and adjustment of the levels of the further fixed frequency bands on the basis of the maximum level of the fixed frequency band which determines the center frequency in line with the shape of the bell curve.

### BACKGROUND OF THE INVENTION

1. Field of the Invention

The present invention relates to a graphic audio equalizer for altering an audio frequency response for selected frequency bands using a plurality of filters of variable level.

2. The Prior Art

A graphic audio equalizer adjusts a plurality of frequency bands of fixed bandwidth and center frequency whose volume can be influenced on an individual basis. Such equalizers are typically provided by means of slide controls associated with the frequency bands. Alternatively, the slide controls can be provided in the form of software, for example on the screen of a PC, and can be influenced by mouse actuation. In the consumer sector, equalizers are regularly designed in a stereo version. As professional instruments, the equalizers are used with more than two channels, according to need.

An alternative to the graphic equalizer is the parametric equalizer. A parametric equalizer can ideally be adjusted in terms of frequency, Q-factor, i.e. width of the filter curve, and level of the center frequency. If these three parameters can be varied just for one frequency, a single-band parametric equalizer is referred to. If, by contrast, the level and Q-factor of a plurality of frequencies can be adjusted, a multiband parametric equalizer is referred to.

While graphic equalizers are frequently used to correct the tone of master signals, stereo sums or to align the main signal with circumstances in a room, parametric equalizers are frequently used for tone shaping. In addition, parametric equalizers can also be found in channel strips on mixing desks.

In principle, a parametric equalizer can be used to attain virtually any desired frequency response, including the bell curve of a parametric equalizer. To simulate this bell curve using a graphic equalizer, each individual frequency band needs to be varied manually using the control element associated therewith until the desired curve is represented. If this frequency response curve produced in such a way needs to be shifted, this means that all or some of the levels already altered need to be reset to zero decibels again using the control elements, and the curve then needs to be simulated manually in the lower or higher frequency range, specifically band by band with a high level of involvement.

There is therefore a need, in principle, for a graphic equalizer which can be used to realize the function of a parametric equalizer on a more variable basis with as little involvement as possible.

### SUMMARY OF THE INVENTION

One object of the present invention is therefore to design a graphic audio equalizer of the type mentioned above for the purpose of simple and problem-free use as a parametric equalizer.

Accordingly, the invention provides for the basic function of a parametric equalizer to be simulated by a graphic equalizer. Specifically, a circuit is provided which is used to adjust the level of a particular number of frequency bands on the graphic equalizer on both sides of the center frequency of the bell curve or filter curve to be produced, on the basis of the selected level of the center frequency such that a bell curve is simulated. A number of frequency bands on the graphic equalizer which are used to form the bell curve thus stipulate the Q-factor, i.e. the width of the filter curve, while the levels of the frequency bands on both sides of the center frequency are coupled to the center frequency's level so as to simulate the shape of the bell curve, so that readjusting the level of the center frequency or the frequency band which stipulates the center frequency results in a corresponding proportional change in the frequency bands situated to the side thereof.

In practice, this means that when the Q-factor of the filter curve has been stipulated, the filter curve can easily be produced and altered by changing the center frequency, for example by varying the level control associated with this frequency. Manual adjustment of the frequency bands which are adjacent at the sides is thus eliminated, which means that the function of a parametric equalizer can be reliably simulated using the graphic equalizer without any problem in accordance with the invention.

According to the invention, the graphic audio equalizer's circuit allows the bell curve or filter curve to be shifted by shifting the corresponding center frequency without needing to alter the side frequency bands manually. This is achieved by virtue of the invention's coupling of the amplitude of the sidebands to that of the center frequency band.

The steepness of the bell curve or filter curve thus depends on the chosen number of adjacent bands in relation to the center frequency band. A small number of adjacent bands results in a steep curve, corresponding to a high Q-factor, whereas a large number of adjacent bands corresponds to a shallow curve, corresponding to a lower Q-factor, for a parametric equalizer.

The inventive circuit for simulating the parametric mode using a graphic equalizer can be produced in different ways. One particularly advantageous implementation of this circuit comprises a digital signal processor for selecting the number of further fixed frequency bands and for adjusting the level thereof, on the basis of the maximum level of the fixed frequency band which determines the center frequency.

In addition, the circuit advantageously comprises a microcontroller for implementing the functions by actuating manual control elements in connection with the formula for Gaussian normal distribution. The use of manual control elements allows the graphic equalizer to be used in parametric mode in an inherently familiar manner. Accordingly, the manual control elements are designed in an inherently known manner for selecting the center frequency, the maximum level of the center frequency and the Q-factor. The control elements can be provided in a manner which is inherently arbitrary. Preferably, control elements are in the form of rotary controls and slide controls. Alternatively, the control elements can be in the form of pushbuttons.

To simplify use, the frequency response can be shown visually on a display. This display is preferably in the form of a liquid crystal screen.

To improve the practical feasibility of the graphic equalizer in parametric mode, the circuit for simulating the parametric equalizer comprises a device for temporarily converting the functions for the respective parametric frequency response change into an actual frequency response change for an audio input signal and a device for final conversion of the functions for the respective parametric frequency response change.

In summary, the inventive simulation of a parametric equalizer using a graphic equalizer provides the following advantages:

a parametric filter curve or bell curve can be produced easily and quickly using a graphic equalizer;

the curve produced can quickly be shifted by altering the center frequency in the entire frequency range just like on a parametric equalizer;

readjustment of all the frequency bands involved in the curve is unnecessary as soon as the center frequency and the Q-factor, i.e. the number of side frequency bands, has been stipulated;

the filter curve obtained can be widened or made narrower quickly and without any problems by changing a single parameter, i.e. the number of side frequency bands;

the currently selected filter curve can be stored;

any number of further filter curves can be produced and stored in line with the same scheme without already stored curves being lost;

alterations within the targeted frequency range of a curve which has already been produced are included proportionally;

an individual frequency band can likewise be altered as quickly as possible in line with the conventional mode of a parametric equalizer; this also applies to altering an entire group of frequency bands (GEQ mode with a parametric condition);

complicated changeover between a conventional graphic equalizer and a graphic equalizer used parametrically is dispensed with; in the latter case, the bandwidth is simply selected to be greater than 1; and

the conventional mode of the graphic equalizer is retained in full.

### BRIEF DESCRIPTION OF THE DRAWINGS

Other objects and features of the present invention will become apparent from the following detailed description considered in connection with the accompanying drawings. It is to be understood, however, that the drawings are designed as an illustration only and not as a definition of the limits of the invention.

In the drawings, wherein similar reference characters denote similar elements throughout the several views:

FIG. 1 schematically shows, in graph form, a frequency response set by a parametric equalizer;

FIG. 2 schematically shows, in graph form, a frequency response set by a parametric equalizer to produce bell curves with high Q-factor;

FIG. 3 schematically shows, in graph form, a frequency response set by a parametric equalizer to produce bell curves with low Q-factor;

FIG. 4 shows the frequency response from FIG. 2, produced by a graphic equalizer;

FIGS. 5 and 6 schematically show the selection of a center frequency and of the Q-factor of a filter curve for simulating a parametric mode using the inventive graphic equalizer;

FIGS. 7 and 8 show the production of the curve shapes in FIGS. 2 and 3, achieved by the inventive design of graphic equalizer for simulating a parametric mode;

FIG. 9 schematically shows, in the form of a block diagram, a first embodiment of the inventive graphic equalizer with a parametric mode; and

FIG. 10 schematically shows, in the form of a block diagram, a second embodiment of the inventive graphic equalizer with a parametric mode.

### DETAILED DESCRIPTION OF THE PREFERRED EMBODIMENT

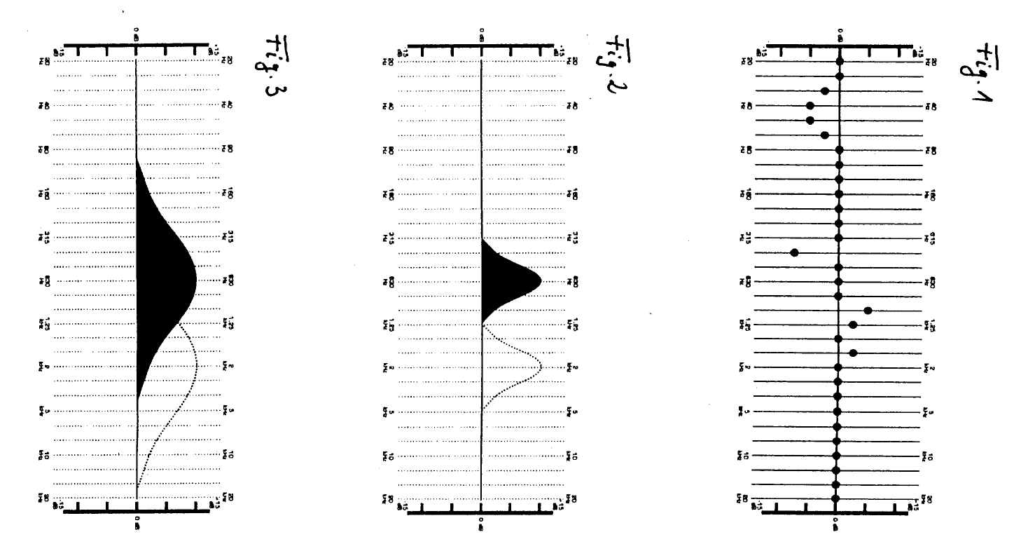

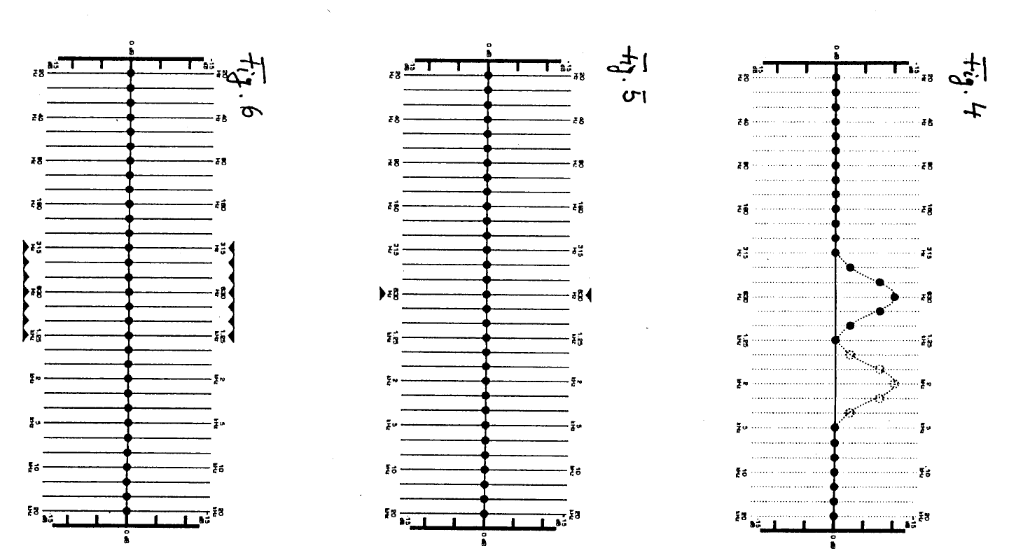

Referring now in detail to the drawings, FIGS. 1 to 8 show the functions of equalizers schematically in graph form. In the graph, the audio frequency response is plotted on the horizontal axis in hertz or kilohertz and the amplitude is plotted on the vertical axis in decibels, from −15 decibels to +15 decibels in the exemplary illustration. These graphs have been produced on an actually embodied equalizer either using control elements on its front panel (for example FIG. 1, in which black dots show the position of the knobs on control elements) or on a screen (for example FIGS. 2 and 3, which plot the curve shape graphically.

FIG. 1 schematically shows, in graph form, the alteration of a frequency band using a graphic audio equalizer in conventional graphic mode. The plurality of frequency bands of fixed bandwidth and center frequency which are conventionally available on a graphic equalizer are shown in FIG. 1 by means of circular black dots, which correspond to the knobs on control elements, for example. For a linear audio frequency response, all of these control element knobs (black dots) come to rest on the zero decibel line in the graph. As FIG. 1 shows, any frequency response can be achieved by actuating the control elements.

The way in which a parametric equalizer works is shown in FIG. 2. A parametric equalizer can be adjusted typically in terms of frequency, Q-factor, i.e. width of the filter curve, and level of a center frequency. In FIGS. 2 and 3, the curves filled black are characterized by a center frequency of 630 Hz. In FIG. 2, the bell curve shown with the center frequency of 630 Hz extends from 315 Hz to 1.25 kHz, i.e. has a width or Q-factor of 935 Hz, while the Q-factor of the bell curve (filter curve) in FIG. 3 is approximately 3.3 kHz. These curve shapes are produced, by way of example, by rotary controls, with one rotary control determining the position of the center frequency while the other determines the Q-factor of the filter curve. Once the Q-factor of the filter curve has been stipulated, the position of the curve can then be shifted simply by adjusting the control element for the center frequency, in FIGS. 2 and 3 into the 2 kHz position (dotted representation of the filter curve).

FIG. 4 shows a simulation of the curve shape from FIG. 2, in that case set using a parametric equalizer, by a graphic equalizer. To produce the bell curve in FIG. 2 using a graphic equalizer, each individual frequency band concerned needs to be set manually to the appropriate level on the graphic equalizer until the desired curve is represented. In the case of FIG. 4, this means that the center frequency of 630 Hz needs to be adjusted by the control element for the 630 Hz frequency band, and that a total of four sideband controllers, respectively two on each side of the center frequency band controller, need to be actuated to give a corresponding amplitude setting. The graphical representation shows that this allows a graphic equalizer to be used to simulate a parametric mode in line with a parametric equalizer.

If, however, the bell curve with the 630 Hz center frequency needs to be simulated, while retaining its shape, at a center frequency of 2 kHz, all the level controllers around the 630 Hz center frequency need to be reset to zero decibels, and a new setting around the 2 kHz center frequency needs to be made in line with the previously explained production of the bell curve having the 630 Hz center frequency. Such a procedure is involved and is therefore less suitable in practice, which is why either a graphic equalizer or a parametric equalizer is used at that point in principle.

However, the graphic audio equalizer according to the invention allows a parametric mode to be simulated, as explained below with reference to FIGS. 5 to 8.

The aim of the invention is to produce the filter curves or bell curves shown in FIGS. 2 and 3 using a graphic equalizer in a simple manner. For this purpose, it is assumed that all the control elements on the graphic equalizer are set to zero, as shown in FIG. 5. Next, the desired center frequency, in this case 630 Hz, is stipulated, as illustrated in FIG. 5 by arrows on the graphic equalizer's 630 Hz frequency band. The center frequency is stipulated in this way using a corresponding suitable control element, for example a rotary control, which inputs this center frequency into a simulation circuit in accordance with the invention.

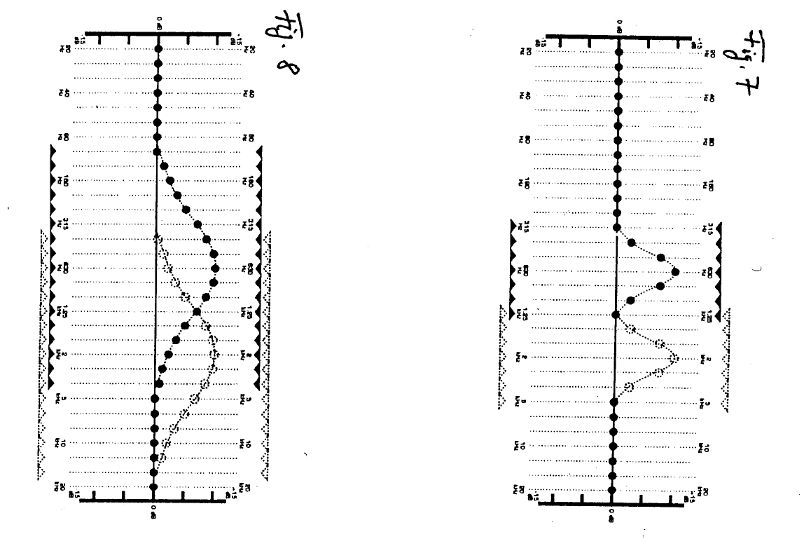

Next, the Q-factor of the filter curve to be produced is stipulated, as shown in FIG. 6, by stipulating the number of side frequency bands on both sides of the center frequency band of 630 Hz, as illustrated by arrows on the corresponding side frequency bands, i.e. on three respective side frequency bands on both sides of the 630 Hz center frequency. For this purpose, corresponding control elements, for example rotary controls, are provided which input these values, i.e. the number and value of the corresponding sideband center frequencies, into the simulation circuit.

In the next step, illustrated in FIG. 7, a simulation circuit receives an input determining whether the level of the center frequency band, which has been chosen above to be 630 Hz, needs to be boosted or cut. In the present case, the center frequency band needs to be boosted. This is done using a corresponding rotary control, for example. Appropriate adjustment values are input into the simulation circuit and, in line with a curve shape previously stored in a memory, prompt a proportional boost (in the present case) to the side bands adjacent to both sides of the center frequency band in said simulation circuit in order to produce the bell curve shown in FIG. 7 (black dots). If this bell curve easily produced in this way needs to be produced with the same Q-factor at the center frequency 2 or needs to be shifted to this frequency, it is merely necessary to actuate the control element for the center frequency in a similar manner to a parametric equalizer. The appropriate sideband frequencies are then concomitantly adjusted in proportion.

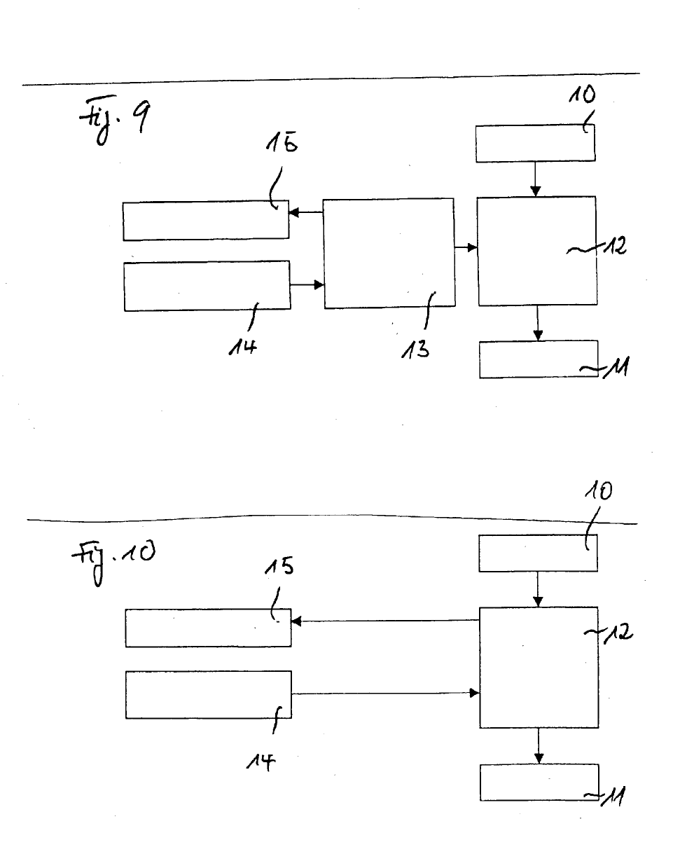

FIG. 8 shows the result of a similar procedure to that explained above with reference to FIGS. 5 to 7, but for the purpose of producing the bell curves with lower Q-factor shown in FIG. 3 using a correspondingly greater number of controllers for the side frequency bands.

A particular advantage of the present invention of achieving a parametric mode with a graphic equalizer is that merely altering or shifting the center frequency allows a curve which has been produced to be shifted through the entire frequency range without the individual frequency bands on the graphic equalizer needing to be readjusted every time.

If a decision has been made to opt for a particular bell curve or filter curve, for example for the filter curve shown in FIG. 7, this setting can be stored in a memory in the circuit, for example, and all the parameters, i.e. center frequency, curve width or number of side frequency bands and level of the new center frequency, are then enabled in order to be able to produce a further new curve. This involves all the settings explained above with reference to FIGS. 5 to 7 being able to be adjusted as desired and stored again. This means that it is no problem to produce even a complex overall curve over the entire frequency range, for example and by way of preference even a high pass filter or low pass filter and a “cow's tail”. If only a single frequency band is selected, however, with this frequency band automatically being geared to the currently chosen frequency, it is also possible for just a single frequency to be influenced, as in the case of a conventional graphic equalizer. All previously stored curve representations are retained in this context, unless a frequency is changed within an already produced curve shape. In this case, the alteration is naturally made in proportion.

A first embodiment of the inventive graphic equalizer with a parametric mode is shown as a block diagram in FIG. 9. Accordingly, the equalizer comprises an input circuit 10 for inputting an audio signal and an output circuit 11 for outputting an audio signal whose frequency response is influenced by the equalizer. Arranged between the input stage 10 and the output stage 11 is a digital signal processor or DSP 12 which undertakes the processing of the entered output signal to the benefit of the output signal. DSP 12 is fed by a microcontroller 13 whose input is connected to a user interface 14, whose output remotely controls the DSP 12 and whose additional output supplies a display apparatus, for example an LCD, with information.

In microcontroller 13, the user interface's stipulation is taken as a basis for detecting the control elements (not shown) for setting the center frequency in the shape of the center frequency band and associated side frequency bands, and corresponding information is forwarded to the microcontroller, which contains a coefficient calculation for representing the desired bell curve (Gaussian distribution function). The bell curve produced in the microcontroller using the interface is output to DSP 12, in which the frequency response of the signal which has been input via input circuit 10 is modified as appropriate.

FIG. 10 shows an alternate embodiment of the equalizer shown in FIG. 9. The equalizer in FIG. 10 differs from that in FIG. 9 by virtue of the microcontroller being dispensed with and by virtue of DSP 12 performing both the coefficient calculation and the processing of the audio signal and the output of a visualization signal to the display 15. In addition, the DSP 12 in the embodiment shown in FIG. 10 has an input for connection to the user interface.

In a manner which is not shown, every variant of the DSP 12 has a memory for storing the bell curve determined using the user interface.

Accordingly, while only a few embodiments of the present invention have been shown and described, it is obvious that many changes and modifications may be made thereunto without departing from the spirit and scope of the invention.

What is claimed is:

1. A graphic audio equalizer for altering an audio frequency response in selected frequency bands using a plurality of filters of variable level, fixed frequency band and fixed center-frequency, comprising:
a circuit for simulating an operation of a parametric audio equalizer to alter an audio frequency response in a shape of at least one bell curve defined by center frequency, Q-factor and maximum level, the following functions being implemented in the circuit:
(a) selection of one of the fixed frequency bands as the center frequency,
(b) selection of further fixed frequency bands on both sides of the fixed frequency band which determines the center frequency in order to stipulate the Q-factor, and
(c) adjustment of levels of the further fixed frequency bands on the basis of the maximum level of the fixed frequency band which determines the center frequency in line with the shape of the bell curve.

2. The equalizer as claimed in claim 1, wherein the circuit has a digital signal processor for selecting a number of further fixed frequency bands and for adjusting a level thereof on a basis of the maximum level of the fixed frequency band which determines the center frequency.

3. The equalizer as claimed in claim 1, wherein the circuit comprises a microcontroller for implementing the functions by actuating manual control elements in connection with a formula for Gaussian normal distribution.

4. The equalizer as claimed in claim 3, wherein the manual control elements are designed for selecting the center frequency, the maximum level of the center frequency and the Q-factor.

5. The equalizer as claimed in claim 3, wherein the control elements are rotary controls.

6. The equalizer as claimed in claim 3, wherein the control elements are slide controls.

7. The equalizer as claimed in claim 3, wherein the control elements are pushbuttons.

8. The equalizer as claimed in claim 1, wherein a display is provided for visually showing the frequency response.

9. The equalizer as claimed in claim 7, wherein the display is a liquid crystal screen.

10. The equalizer as claimed in claim 1, wherein the circuit has a device for temporarily converting the functions for a respective parametric frequency response change into an actual frequency response change for an audio input signal and a device for final conversion of the functions for the respective parametric frequency response change.
